(19) United States
(12) Patent Application Publication
(10) Pub. No.: US 2014/0176084 A1
(43) Pub. Date: Jun. 26, 2014

(54) System and Method for the Adaptive Management of a Battery System

(71) Applicant: Paul Geantil, San Diego, CA (US)

(72) Inventor: Paul Geantil, San Diego, CA (US)

(21) Appl. No.: 13/722,473

(22) Filed: Dec. 20, 2012

(51) Int. Cl. H02J 7/00; G01R 31/36

(52) U.S. Cl. CPC H02J 7/007; G01R 31/3606
USPC 320/152; 320/162; 324/427

(57) ABSTRACT

The present invention relates generally to a method and apparatus for the management of individual cells in a battery system. More particularly, the present invention relates to the control of charging a battery system such that the cells stay balanced and the ability to produce a battery system profile and cell profile to adapt to the changes of the cells within the battery system.

### TECHNICAL FIELD

The present invention relates generally to a method and apparatus for the management of individual cells in a battery system over time. More particularly, the management of a battery system as it changes over time to enable the maximum desired condition of the pack and an individual cell.

### BACKGROUND

Typically, battery systems, which may include an individual cell or a plurality of individual cells. A “cell” can mean a single electrochemical cell comprised of the most basic units, i.e. a positive plate, a negative plate, and an electrolyte. However, as used herein, the term is not so limited and may include a group of basic cells that can comprise a single unit as a component of a battery system and the use of the latest in battery chemistries, i.e. lithium and lithium combinations. A battery or battery system is a series, or parallel connection of units, or individual cells.

There is a tendency for each cell within individual batteries, when connected in series, to have different characteristics, such as energy storage capacity and discharge rates. These differences are caused by many variables including, but not limited to, temperature, initial tolerances, material impurities, porosity, electrolyte density, surface contamination, and age. A low-capacity cell will typically charge and discharge more rapidly than the other cells and such can change or be more drastic over time and charge cycles. An overly charged and discharged cell develops poor recharging characteristics and can be permanently damaged. A damaged cell will affect the operating characteristics of the entire battery system. The damaged battery will have lower capacity and will become discharged more rapidly than a healthy battery. The failure of an individual cell can cause substantial damage to the battery system and accompanying equipment. Therefore, a need exists for a system to monitor a battery system to prevent over charging and discharging of cells.

The use of a battery management system to overcome over charging and discharging of the batteries is well known in the art. Typically a battery management system monitors the charging and discharging of the batteries by monitoring unit parameters such as voltage of the batteries, which is then recorded and analyzed by a microprocessor to determine the condition and state of each cell in the battery system. Additionally, it is common for a battery management system to control bleed off resistors, where a resistor is connected to an individual cell such that the bleed off resistor is bleeding off unwanted energy provided to that cell while charging a battery system. Although the use of this type of battery management systems resolves many problems it is still limited when a charge is applied to a battery system in that the battery management system can only discharge the amount of current equal to the resistance value of the bleed off resistor. Such that in the event one cell is charged more quickly than another, the bleed off resistor can only bleed off the energy equivalent to the value of the bleed off resistor and therefore the one cell may still receive unwanted current and become overcharged thereby damaging the cell. In such event the only solution would be to reduce the overall charge to the battery system thereby lengthening the time it takes to recharge the battery system. Also, the current battery management systems are not able to adapt to the changes in a battery system over time and charge cycles.

### SUMMARY

The deficiencies of the prior art are substantially overcome by the battery management system of the present invention which includes the method of pulsing the bleed off resistor such that the bleed off resistor does not overheat and the method of developing a profile of the battery system and a profile of each cell in the battery system such that the profile of the battery system and each cell in the battery system at various points in the life of the battery system such that the battery management system can be smartly configured to adapt to the changes of the cell and modify the charging to enable the maximum performance of the battery management system. Furthermore upon enabling multiple profiles one can see the degradation characteristics of a battery pack and a battery cell over time and charge cycles.

In a preferred embodiment of the present invention four cells can be logically placed in a battery system having a battery management system or a plurality of battery systems having a battery management system. The battery management system includes a bleed off resistor for each cell, a current meter to count the current provided to each cell and a temperature sensor monitoring each cell or battery system. At full charge the voltage level of each cell is at 3.6 volts whereas a depleted cell would read 2.5 volts. In a battery system one battery may charge more quickly than the others based on the chemical and physical makeup of the cell. High current can be passed through the battery system to quickly charge each cell. In the event one cell in the battery system becomes charged sooner the battery management system is smartly configured utilizing the control of a microprocessor to connect the bleed off resistor to that charged cell thereby causing power to bleed off of that cell such that the cell is not overly charged and the total current to the battery system does not have to be reduced until all cells in the battery system are fully charged and read 3.6 volts. Under the present invention the microprocessor is smartly configured with a temperature sensor such that the microprocessor will disconnect the bleed off resistor at a temperature level determined to be detrimental to the system. Additionally the microprocessor is smartly configured to connect the bleed off resistor again when the bleed off resistor is cooled to a heat determined to be safe to bleed off additional power from the cell.

Another particularly innovative aspect of the present invention is realized when the temperature level determined to be detrimental to the system is reached the microprocessor is smartly configured to pulse the connection of the bleed off resistor to the cell such that energy is still bleeding off and the temperature can be maintained at a desired level. This enables the ability to continue bleeding off unwanted current instead of completely disconnecting the bleed off resistor leaving the battery vulnerable to overcharging or reducing the charging of the battery system such that the recharging of the battery system takes longer. It is further realized that one can exceed the wattage rating of the bleed off resistor for a short time in an effort to bleed off more heat as long as the bleed off resistor can be pulsed to maintain a desired temperature.

Another advantage of the present invention is realized when a current sensor is enabled to sense the current going into and out of each cell. Under the current invention a cell profile is generated by placing a current sensor for the cell that is enabled to track the amount of current going into the cell and how much current is going out of the cell. By calculating the amount of current going into and out of the cell one can generate a cell profile representing the capacity of the cell. More specifically, during one of the initial charging cycles of the battery system where the battery system is mostly depleted and then charged a cell profile is generated and stored in non-volatile memory for each cell in a battery system and the overall battery system profile can be generated. This battery system profile includes a value which represents the capacity of each cell or a grouping of a number of cells. Over a predetermined amount of time a new battery system profile is generated which includes a value which represents the capacity of each cell or grouping of a number of cells. The battery management system is smartly configured to compare the differences between the battery system profile generated at one of the initial charging cycles of the battery system and the most recently generated battery system profiles that is generated from a more recent charge cycle and generate a battery system use profile which includes the information needed to manage the charging of the battery system taking into consideration the changes in the individual battery cell. The process of providing a battery system use profile as described herein can be generated any number of times to account for changes in the battery system or battery cell over time and charge cycles. Furthermore the battery management system can use the battery system use profile and turn on the connection or pulse the connection of the bleed off resistor of the cell with less capacity sooner thereby allowing more power to bleed off and overcoming the disadvantages that leave the cell vulnerable to overcharging. As cells degrade differently over time the battery system use profile will include the information to adapt to the changes of each cell enabling the ability to continually manage the cell with less capacity overcoming the disadvantages that leave the cell vulnerable to overcharging.

Yet another advantage of the battery system use profile and the cell profile is realized when the battery system or cell has passed its life for a particular application but not passed its life for every application. In this case, the battery system or cell has a battery system profile and a battery use profile which can be used to identify the historic characteristics of the battery system or cell. This is helpful when identifying the state of health of the battery system or cell or the remaining capacity of the cell for an additional or secondary application once the battery system or cell has passed its life for a particular application.

### BRIEF DESCRIPTION OF THE DRAWINGS

FIG. 1 is a block diagram representing prior art

FIG. 2 is a block diagram illustrating one embodiment of the invention

FIG. 3 represents a battery system

FIG. 4 is a graph representing the effects of pulsing the bleed off resistor connection to a cell

FIG. 5 represents a cell profile of two cells

FIG. 6 represents a preferred embodiment of the present invention as it relates to cell profile

FIG. 7 represents an embodiment of the method for creating a battery cell profile

FIG. 8 represents a method for determining the capacity of the cell in a battery system

### DETAILED DESCRIPTION OF THE DRAWINGS

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

A portion may be described herein in terms of functional and/or logical block components and various processing steps. It should be appreciated that such block components may be realized by any number of hardware, software, and/or firmware components configured to perform the specified functions. For example, an embodiment of the invention may employ various integrated circuit components, e.g., memory elements, logic elements, look-up tables, or the like, which may carry out a variety of functions under the control of one or more microprocessors or other control devices. In addition, those skilled in the art will appreciate that the present invention may be practiced in conjunction with any number of batteries, battery management systems, and controllers and that the system described herein is merely one exemplary application for the invention.

The overall purpose of the battery management system is to automatically manage each individual battery cell, one of a plurality of cells in a battery, such that the overall health of the cell is maintained. Maintaining battery health requires monitoring of key parameters of the battery in various states. Such key parameters include current being applied to each cell, current bleeding off at each cell, and current being drained from each cell and temperature.

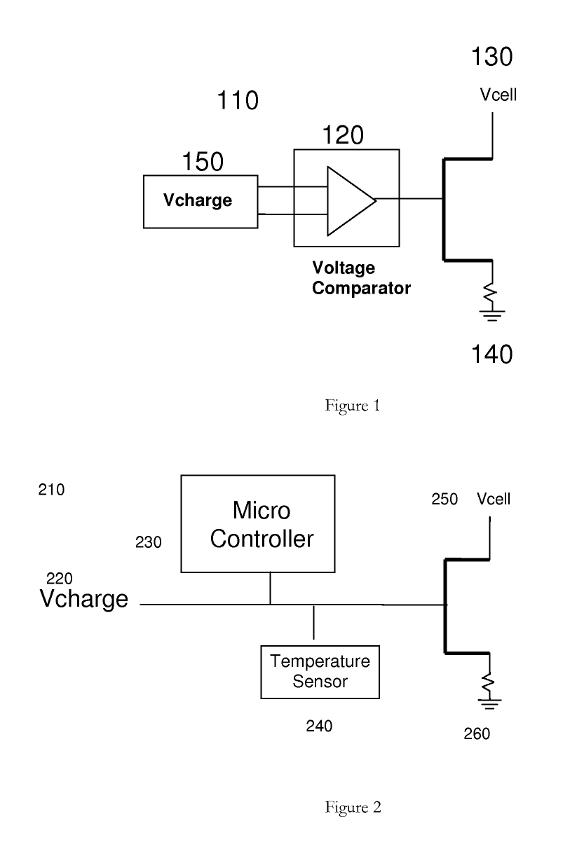

As represented in FIG. 1, the typical battery management systems (110) includes a battery or cells within a battery box (130), a voltage comparator (120), a bleed off resistor (140) and a charging voltage (150). In such a traditional system, in the event the voltage from the voltage cell (130) came to a level which represents full charge the voltage comparator (120) consistently compares the charging voltage (150) to the voltage of the cell (130) and in the event the voltage of the cell (130) has reached desired voltage level representing the cell is fully charged the shunt resistor (140) is connected to the charging voltage (150) thereby bleeding off the charging voltage such that the battery cell is not overly charged.

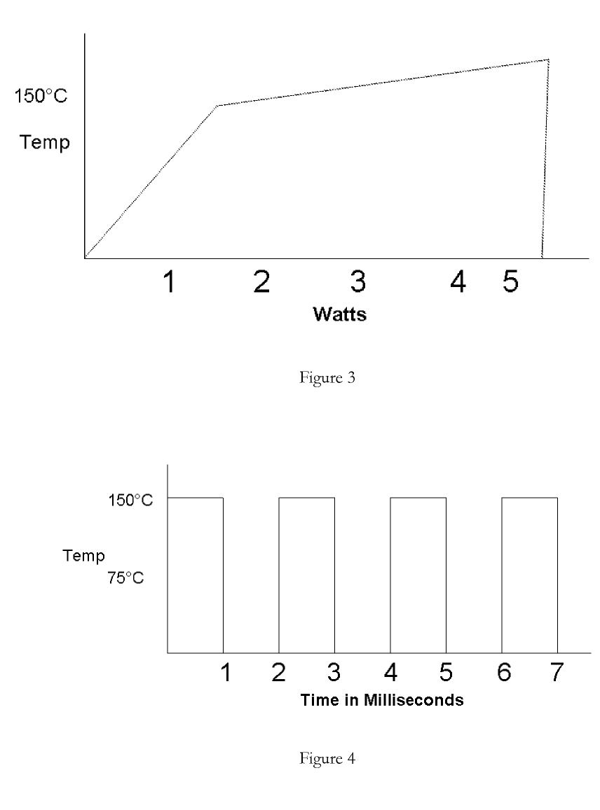

FIG. 2, represents one embodiment of the present invention of a battery management system (210), whereby the charging voltage (220) is smartly connected to a cell (250) and the resistor (260) such that the microcontroller (230) is enabled to disconnect the bleed off resistor (260) in the event the temperature of the bleed off resistor is too high as read by the temperature sensor (240). In practice, the microcontroller (230) is smartly configured to connect and disconnect the bleed off resistor (260) such that the bleed off resistor (160) can bleed off any charging voltage supplied to the cell (250). In the event the cell (250) becomes fully charged the microcontroller (230) will connect the bleed off resistor (260) to bleed off unwanted energy thereby protecting the cell (250) from becoming over charged. In the event the bleed off resistor (240) is bleeding off too much energy, the temperature of the bleed off resistor (240) can exceed the limitations of the bleed off resistor (260) causing it to fail or turn off thereby leaving the cell vulnerable to overcharging. Under the present invention when the bleed off resistor (260) exceeds its limitation in temperature as represented in FIG. 3 as 150 degrees Celsius the bleed off resistor is then disconnected. This leaves the charging voltage to remain high and causing over charging of the cell.

As represented in FIG. 4 which is another preferred embodiment of the present invention where the microcontroller can be smartly configured to pulse the bleed off resistor. This pulsing can occur at a frequency where the connection, between zero milliseconds and one millisecond, and the disconnection, between one millisecond and two milliseconds, is one cycle. Such cycle time can vary from a microsecond to sixty minutes depending on the temperature level. As mentioned herein the temperature level depends on the amount of current being bleed off from the cell but it can also depend on other factors like environment temperatures. As represented in FIG. 4, and under the present invention once the bleed off resistor has reached its maximum limitation of bleeding off energy which is represented in FIG. 4 by the limitation of heat of 150 degrees Celsius the microcontroller can turn off the bleed off resistor for a short time, one millisecond, thereby allowing the bleed off resistor to cool. Once the bleed off resistor has cooled the microcontroller is smartly configured to reconnect the bleed off resistor for one millisecond to bleed off additional energy thereby pulsing the bleed off resistor. This enables continued protection of the battery while maintaining the temperature of the bleed off resistor at a desired state. Furthermore, with the pulsing of the bleed off resistor and the input of the temperature one can exceed the maximum wattage of the bleed of resistor for a short time as long as the temperature of the bleed off resistor is kept at desired levels. This enables one to allow high amounts of charging voltage for a short period of time thereby enabling quicker charging of the battery system.

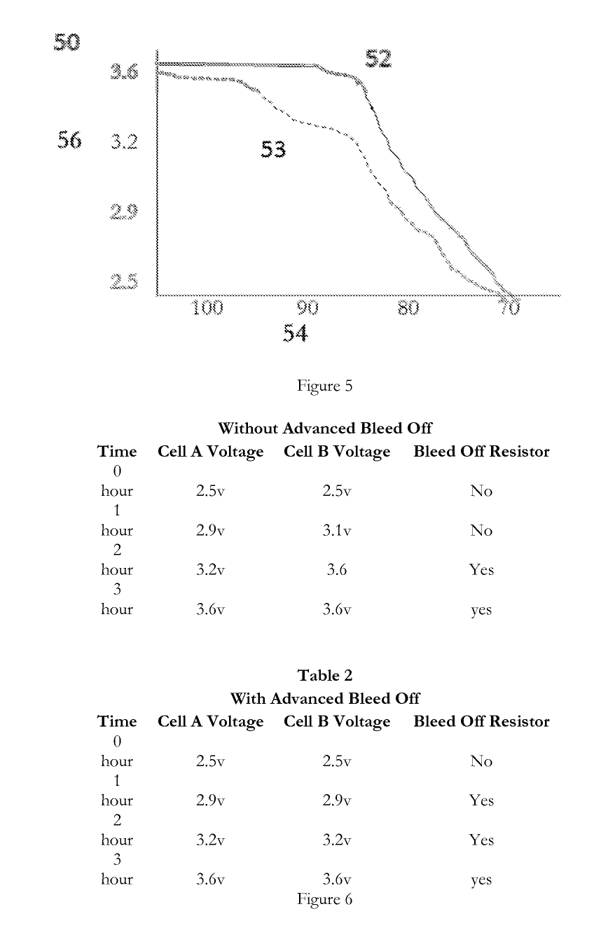

As represented in FIG. 5 which is another preferred embodiment of the present invention as it relates to the cell profile wherein the chart (50) shows two cell profiles, cell (53) and cell (54) where cell (53) has less capacity than cell (52). The capacity is represented on this chart by taking the value line (54) which represents a percentage of the overall current the cell can receive and/or distribute, with the value line (56) which represents the voltage of the cell. As it relates to the present invention, when charging cell (52) and cell (53), cell (53) will reach its maximum voltage well before cell (52). Once one practicing the current invention knows that cell (53) will reach its maximum voltage sooner than cell (52) one can turn on and/or pulse the bleed off resistor during the charging process such that the cell (52) and cell (53) reach their maximum voltage at relatively the same time.

As represented in FIG. 6 which is another preferred embodiment of the present invention as it relates to cell profile wherein Table 1 titled Without Advanced Bleed Off and Table 2 titled With Advanced Bleed Off shows the differences when using advanced bleed off. In Table 1 the voltage level between Cell A and Cell B will vary as they are charged over time specifically due to the cell's capacity to hold a charge. As represented in the table, if the cell holds less capacity it will charger sooner and the voltage level will increase faster than the battery that holds a larger capacity of charge. If the bleed off resistor is turned on only when the battery is fully charged, which is shown in Table 1 as 3.6 volts then the charge level and voltage during the charging cycle as represented over time in Table 1 between Cell A and Cell B is not matched. In this embodiment if one was going to only charge their battery for 2 hours it would create a voltage level variance between Cell A and Cell B. As shown in Table 2 where the bleed off resistor is turned on in advance because one knows that Cell B has a lower capacity and therefore reaches a full charge sooner, than one can turn on the bleed off resistor sooner, thereby advancing the time in which the bleed off resistor turns on in an effort to maintain the voltage levels of Cell A and Cell B at the same level through the time it takes to charge the battery to full charge. In this embodiment if one was to only charge the battery for 2 hours Cell A and Cell B would be at the same voltage throughout the charge cycle and at 2 hours as represented in the table as 3.2 volts. Additionally, in this embodiment the cells would reach full charge at the same time.

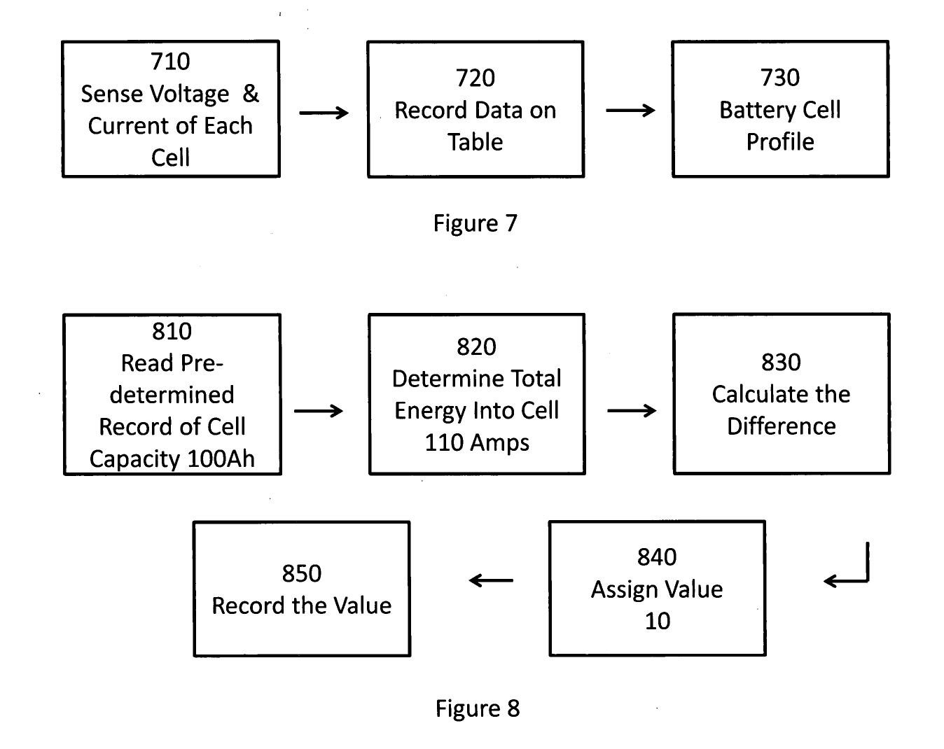

One embodiment of the method for creating a battery system profile is represented in FIG. 7 where the microcontroller is smartly configured such that during one of the initial full charging cycles of a battery system wherein the battery cell voltage has dropped to a predetermined amount, for example 2.5 volts, and then charged to a pre-determined full charge, for example 3.75 volts, whereby in that process the battery management system generates a battery system profile. As provided in FIG. 7 the method is performed by determining the time to generate an initial battery system and cell profile which is typically during the initial full charging cycles of a battery system for a particular application and upon such time instructing various sensors located within the battery system or on the cell to sense cell voltage and to count the amount of current going into each cell in the battery system while charging (710) and record voltage and current going into each cell on a table in number of predetermined intervals of time while charging into non-volatile memory via a table (720) and assign a value (as shown in FIG. 8), which represents the capacity of each cell and compare the value with the other cells in the battery system to identify the lowest capacity. The microprocessor is then smartly configured to produce a battery system profile (730) such that it is enabled to turn on or cause another process to turn on the bleed off resistor or pulsing of the bleed off resistor on the cells with the lower capacities such that the cells are charged equally in relation to their capacities of the other cells within the battery system. This process can be run continually such that the cells are balanced throughout the charge cycle.

One embodiment of the method for assigning a value, which represents the capacity of each cell and compare the value with the other cells in the battery system to identify the lowest capacity, is represented in FIG. 8. The method includes having a predetermined record of the total capacity of the cell by way of the specification provided by the cell manufacture or through a previous generated battery system profile. As represented in FIG. 8, the predetermined cell capacity is 100 Ah (810). The battery management system is smartly configured such that upon determining (820) the total amount of current that went into each cell during the charge cycle, which is stored for each cell into non-volatile memory during an initial charge cycle where the cell is fully charged from a fully discharged state, the battery management system compares (830) that value with the predetermined record of the total capacity of the cell which is represented in Ahs and in this example is 100 Ahs (810). If the value is higher than 100 amps as represented in FIG. 8 as 110 amps (820) a value of ten is calculated (840) by the battery management system and recorded in a table (850). When this process is completed for each cell in the battery system the battery management system will have a battery system profile for that battery system, which then enables the innovative management described herein. If the value upon determining (820) the total amount of current that went into each cell during the charge cycle, which is stored for each cell into non-volatile memory during an initial charge cycle where the cell is fully charged from a fully discharged state is lower than 100 amps, not represented in FIG. 8, as 90 a value of minus ten calculated by the battery management system (840) and recorded (850) in a table. Upon calculating the values of each cell in the battery system the battery management system then produces a battery system profile as represented in FIG. 7 and recorded into non volatile memory.

One particular advantage of the invention as represented in FIG. 7 and FIG. 8 when considered in the combination is realized over time and upon completion of many charge cycles where multiple battery system profiles are generated which includes a value representing the capacity of each cell where the characteristics of each cell can be ascertained through the review of each cell's capacity over time, and upon completion of many charge cycles, and when comparing each cell with other cells in the pack. Such characteristics enable the ability to predict the characteristics of each cell over future use.

What is claimed is:

1. A battery management system for managing the charging of cells, the system includes:
various sensors to sense voltage and count the amount of current going into a cell;
a microcontroller; and
non-volatile memory for recording data;
wherein the microcontroller is smartly configured to generate a cell profile through the recording of the amount of current going into a cell during a full charge cycle where the cell was fully depleted.

2. A battery management system of claim 1, wherein the management system includes:
a temperature sensor; and
a bleed off resistor for bleeding off energy to a battery system or cell;
wherein the battery management system is smartly configured to connect the bleed of resistor to the cell with least capacity during a charge cycle

3. A method for generating a battery system profile, the method includes the steps of:
reading the predetermined cell capacity;
reading the battery cell profile;
calculating the difference between a predetermined cell capacity and the battery cell profile;
assigning a value which represents the capacity of the cell for each cell in a battery system; and
generating a battery system profile.

4. A method for generating a battery system profile as in claim 3, wherein the method is performed during one of the initial battery charge cycles where the battery is fully charged from a fully depleted state.

5. A method for generating a battery system profile as in claim 3, wherein the method is not performed during one of the initial battery charge cycles wherein the battery is fully charged from a fully depleted state.
